(19) United States
(12) Patent Application Publication
(10) Pub. No.: US 2007/0174756 A1
(43) Pub. Date: Jul. 26, 2007

(54) Reproducing circuit

(75) Inventor: Michiaki Yoneda, Kanagawa (JP)

Correspondence Address: WOLF GREENFIELD & SACKS, P.C., 600 ATLANTIC AVENUE, BOSTON, MA, 02210-2206, US

(73) Assignee: Sony Corporation, Tokyo (JP)

(21) Appl. No.: 11/654,739

(22) Filed: Jan. 18, 2007

(30) Foreign Application Priority Data
Jan. 23, 2006 (JP) JP2006-013306

(51) Int. Cl. G11C 29/00

(52) U.S. Cl. 714/768

(57) ABSTRACT

A reproducing circuit includes an output circuit that selectively outputs serial two-channel pulse code modulation data and serial two-channel direct stream digital data; a digital-to-analog converter circuit that converts digital data into a first-channel analog signal and a second-channel analog signal; and a conversion circuit. The two-channel pulse code modulation data includes first-channel pulse code modulation data and second-channel pulse code modulation data that are arranged alternately word by word. The two-channel direct stream digital data includes first-channel direct stream digital data and second-channel direct stream digital data that are arranged alternately word by word.

### CROSS REFERENCES TO RELATED APPLICATIONS

The present invention contains subject matter related to Japanese Patent Application JP 2006-013306 filed in the Japanese Patent Office on Jan. 23, 2006, the entire contents of which are incorporated herein by reference.

### BACKGROUND OF THE INVENTION

1. Field of the Invention

The present invention relates to reproducing circuits.

2. Description of the Related Art

Generally, digital audio data used in digital audio apparatuses are based on a two's complement system acquired by pulse code modulation (PCM) (hereinafter, such digital audio data is referred to as “PCM data”). For example, PCM data used in compact discs (CDs) is digital data obtained by quantizing the original analog audio signal into 16 bits per sample at a sampling frequency of 44.1 kHz.

Referring to FIG. 5, “PCM_DATA” represents an example of PCM data output from a large-scale integrated circuit (LSI) for digital audio. That is, the PCM data PCM_DATA is serially output from the LSI. The PCM data PCM_DATA includes a plurality of words, and one word corresponds to one sample. In the example shown in FIG. 5, one sample has 32 bits. Thus, one word has 32 bits.

The PCM data PCM_DATA includes bits L0 to L31 of left-channel digital audio data and bits R0 to R31 of right-channel digital audio data that are alternately arranged word by word. Each word is LSB first.

In contrast to the PCM data PCM_DATA, digital data obtained by converting the original analog audio signal (see part (a) of FIG. 6) into a serial one-bit data string (see part (b) of FIG. 6) by ΔΣ modulation is known.

Such digital data (see part (b) of FIG. 6) obtained by ΔΣmodulation is called “direct stream digital (DSD) data”. The DSD data DSD_DATA is also a pulse-number modulation signal in which the number of pulses changes in proportion to the amplitude of the original analog audio signal. The DSD data DSD_DATA is adopted as a data format used when music data (digital audio data reproduced as music) is recorded or reproduced on Super Audio CD (SACD™), so that recording or reproducing with high-quality sound can be achieved.

Digital-to-analog-(D/A-) converting ICs that support both PCM data PCM_DATA and DSD data DSD_DATA are available. When such a D/A-converting IC, which supports both the PCM data PCM_DATA and DSD data DSD_DATA, performs D/A conversion, for example, digital data is supplied to the D/A-converting IC, as shown in FIGS. 7A and 7B. In FIGS. 7A and 7B, reference numeral 33 denotes the D/A-converting IC. FIG. 7A shows a case where D/A conversion is performed on PCM data PCM_DATA, and FIG. 7B shows a case where D/A conversion is performed on DSD data DSD_DATA.

In order to perform D/A conversion on the PCM data PCM_DATA, the PCM data PCM_DATA is supplied to the IC 33 as shown in FIG. 7A, and a channel clock LRCK and a bit clock BCK are also supplied to the IC 33 as shown in FIG. 5. In this case, the channel clock LRCK is set to “1” when a word of the PCM data PCM_DATA is in the left channel and set to “0” when a word of the PCM data PCM_DATA is in the right channel. In addition, the bit clocks BCK are clocks that are synchronized with the bits LO to L31 and the bits R0 to R31 of the PCM data PCM_DATA.

In addition, a master clock MCK is supplied to the IC 33. When the sampling frequency for the original analog audio signal is represented as a frequency of fs, the channel clock LRCK has a frequency of fs, the bit clock BCK has a frequency of 64 fs, and the master clock MCK has a frequency of 128 fs.

Then, in the IC 33, a left-channel word and a right-channel word of the PCM data PCM_DATA are synchronized with each other in accordance with the channel clock LRCK and the bit clock BCK. In addition, the left-channel word and the right-channel word, which are in synchronization with each other, are D/A-converted in accordance with the master clock MCK, and analog audio signals L and R are output from the IC 33.

In contrast, in order to perform D/A conversion on the DSD data DSD_DATA, left-channel DSD data DSD_L and right-channel DSD data DSD_R are supplied to the IC 33, and a bit clock BCK and a master clock MCK are also supplied to the IC 33, as shown in FIG. 7B. In this case, the bit clock BCK has a frequency of 32 fs, and the master clock MCK has a frequency of 128 fs.

Then, in the IC 33, integration is performed on the left-channel DSD data DSD_L and the right-channel DSD data DSD_R to D/A-convert the left-channel DSD data DSD_L and the right-channel DSD data DSD_R into analog audio signals L and R. Then, the analog audio signals L and R are output from the IC 33.

Examples of the above-mentioned D/A-converting IC 33 are “CS4391” manufactured by Cirrus Logic Inc. and “PCM1702” manufactured by Burr Brown Corporation.

An example of such a D/A-converting IC according to the related-art is described, for example, in “Super Audio CD—Super Audio CD to wa” (Super Audio CD—What is Super Audio CD?), written by an unknown author, issued by Super Audio CD Division, HENC Audio Group, Sony Corporation, on Oct. 14, 2005 (searched on Dec. 28, 2005), Internet (URL: http://www.super-audiocd.com/aboutsacd/format.html).

### SUMMARY OF THE INVENTION

As described above, the D/A-converting IC 33 is capable of appropriately performing D/A conversion of the PCM data PCM_DATA and the DSD data DSD_DATA. In addition, the PCM data PCM_DATA in a format suitable for the D/A-converting IC 33 can be acquired from a digital audio LSI.

However, when the DSD data DSD_DATA is output from the digital audio LSI, the DSD data DSD_DATA includes 32-bit left-channel DSD data DSD_L and 32-bit right-channel DSD data DSD_R that are arranged alternately, as shown in FIG. 8. Thus, DSD data output from the LSI is not directly supplied to the D/A-converting IC 33 explained with reference to FIGS. 7A and 7B. Obviously, LSIs for digital audio data that are capable of outputting both PCM data PCM_DATA and DSD data DSD_L and DSD_R, which are suitable for the D/A-converting IC 33 shown in FIGS. 7A and 7B, are available. However, such LSIs are not mass-produced and are expensive.

It is desirable to appropriately perform D/A conversion by the D/A-converting IC 33 shown in FIGS. 7A and 7B even when DSD data DSD_DATA output from an LSI is DSD data shown in FIG. 8.

A reproducing circuit according to an embodiment of the present invention includes an output circuit that selectively outputs serial two-channel pulse code modulation data and serial two-channel direct stream digital data; a digital-to-analog converter circuit that converts digital data into a first-channel analog signal and a second-channel analog signal; and a conversion circuit. The two-channel pulse code modulation data includes first-channel pulse code modulation data and second-channel pulse code modulation data that are arranged alternately word by word. The two-channel direct stream digital data includes first-channel direct stream digital data and second-channel direct stream digital data that are arranged alternately word by word. When the two-channel pulse code modulation data is supplied to the digital-to-analog converter circuit, the digital-to-analog converter circuit converts the two-channel pulse code modulation data into the first-channel analog signal and the second-channel analog signal. When the first-channel direct stream digital data and the second-channel direct stream digital data are supplied to the digital-to-analog converter circuit, the digital-to-analog converter circuit converts the first-channel direct stream digital data and the second-channel direct stream digital data into the first-channel analog signal and the second-channel analog signal. The conversion circuit separates the two-channel direct stream digital data into the first-channel direct stream digital data and the second-channel direct stream digital data and includes shift registers that simultaneously output the first-channel direct stream digital data and the second-channel direct stream digital data, which are separated from each other. In order to convert the two-channel pulse code modulation data into the first-channel analog signal and the second-channel analog signal, the two-channel pulse code modulation data output from the output circuit is directly supplied to the digital-to-analog converter circuit. In order to convert the two-channel direct stream digital data into the first-channel analog signal and the second-channel analog signal, the two-channel direct stream digital data output from the output circuit is subjected to the separation and synchronization by the conversion circuit and then supplied to the digital-to-analog converter circuit.

Accordingly, even if an LSI does not support a format of DSD data, a D/A-converting IC is capable of performing D/A conversion on the DSD data. An expensive LSI is not used for performing such D/A conversion.

### BRIEF DESCRIPTION OF THE DRAWINGS

FIG. 1 is a schematic diagram showing an application of an embodiment of the present invention; and

FIG. 2 is a schematic diagram for explaining the embodiment of the present invention;

FIG. 3 is a schematic diagram showing the embodiment of the present invention;

FIG. 4 is a timing chart for explaining an operation of a circuit shown in FIG. 3;

FIG. 5 is a waveform chart for explaining the embodiment of the present invention;

FIG. 6 includes waveform charts for explaining the embodiment of the present invention;

FIGS. 7A and 7B are illustrations for explaining the embodiment of the present invention; and

FIG. 8 is a waveform chart for explaining the embodiment of the present invention.

### DESCRIPTION OF THE PREFERRED EMBODIMENTS

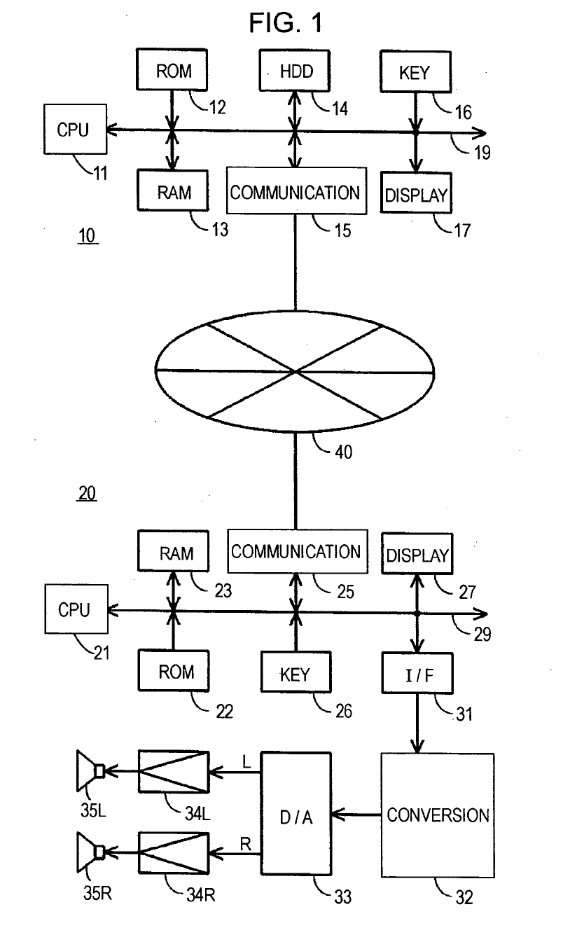

An example of a configuration of the entire system will be described. FIG. 1 shows an example of an audio client-server system used in homes and the like. Reference numeral 10 denotes a server, reference numeral 20 denotes a client, and reference numeral 40 denotes a network, such as a local-area network (LAN). As described below, an embodiment of the present invention is applicable to the client 20. The client 20 performs D/A conversion on PCM data PCM_DATA and DSD data DSD_DATA to reproduce music.

That is, the server 10 includes a central processing unit (CPU) 11 that executes programs, a read-only memory (ROM) 12 in which various programs are written, and a random-access memory (RAM) 13 used as a work area. The CPU 11, the ROM 12, and the RAM 13 are connected to a system bus 19. A hard disk device 14, which serves as a mass storage device, is connected to the system bus 19.

Music data of music to be supplied to the client 20 is stored in the hard disk device 14. The music data is stored in the hard disk device 14 in the form of a file of PCM data PCM_DATA or a file of DSD data DSD_DATA.

A table is provided in the hard disk device 14. Information on music and music data stored in the hard disk device 14, such as the names of albums, the names of songs, the names of artists, information on whether music data is PCM data PCM_DATA or DSD data DSD_DATA, and information on sampling frequencies, the number of channels, the number of bits, and the like, are stored in the table. Such information is used, for example, when the client 20 requests for downloading of music.

The server 10 also includes a communication interface 15. The communication interface 15 is provided for connecting the server 10 to the client 20 via the network 40 in accordance with the transmission control protocol/internet protocol (TCP/IP). Thus, the communication interface 15 is connected to the system bus 19 and to the network 40. The server 10 also includes, as user interfaces for a music administrator, various operation keys 16 and a display unit 17, such as a light-emitting diode (LED), so that the music administrator is able to operate the server 10 and to monitor the state of the server 10.

In contrast, the client 20 includes a CPU 21 that executes programs, a ROM 22 in which various programs are written, and a RAM 23 used as a work area. The CPU 21, the ROM 22, and the RAM 23 are connected to a system bus 29.

The client 20 also includes a communication interface 25. The communication interface 25 is provided for connecting the client 20 to the server 10 via the network 40 in accordance with the TCP/IP. Thus, the communication interface 25 is connected to the system bus 29, and is connected to the network 40 when music is downloaded. The client 20 also includes, as user interfaces, various operation keys 26 and a display unit 27, such as a liquid crystal display (LCD), so that a user is able to operate the client 20 and to monitor the state of the client 20.

In this example, a conversion circuit 32 is connected to the system bus 29 via an interface circuit 31, and a D/A-converting IC (that is, a D/A converter circuit) 33 is connected to the conversion circuit 32. In this case, the interface circuit 31 is subjected to large-scale integration together with the communication interface 25 and the like. As described below, the conversion circuit 32 is provided for converting DSD data DSD_DATA into a format that is capable of being subjected to D/A conversion by the IC (D/A converter circuit) 33. When music is reproduced from PCM data PCM_DATA, processing of the conversion circuit 32 is bypassed.

In addition, the IC (D/A converter circuit) 33 is configured to D/A-convert PCM data into left-channel analog audio data and right-channel analog audio data and to D/A-convert DSD data converted by the conversion circuit 32 into left-channel analog audio data and right-channel analog audio data. Analog output terminals of the IC (D/A converter circuit) 33 are connected to speakers 35L and 35R via amplifiers 34L and 34R, respectively.

An operation will now be described. In order to reproduce music stored in the server 10, the user of the client 20 designates the music to the server 10. Music may be designated in a generally known procedure. For example, the user may directly input the name of desired music using the operation keys 26. Alternatively, the names of music are narrowed down hierarchically every time a condition, such as the name of an artist or the name of an album, is input so that the user is able to finally determine the name of desired music.

When desired music is designated, the server 10 refers to the table contained in the hard disk device 14. The server 10 performs conversion into the name of a DSD file corresponding to the designated music, and reads a file of the desired music (a file in the format of PCM data PCM_DATA or a file in the format of DSD data DSD_DATA) from the hard disk device 14 in accordance with the name of the DSD file. The read file is transmitted from the server 10 to the client 20 via the network 40.

In the client 20, the contents of the transmitted file are processed correspondingly in accordance with the PCM data PCM_DATA or the DSD data DSD_DATA to reproduce the music.

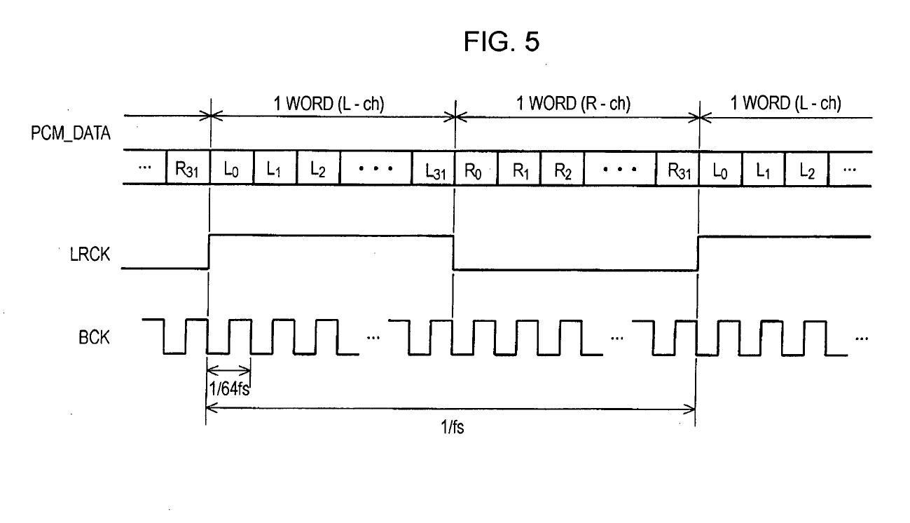

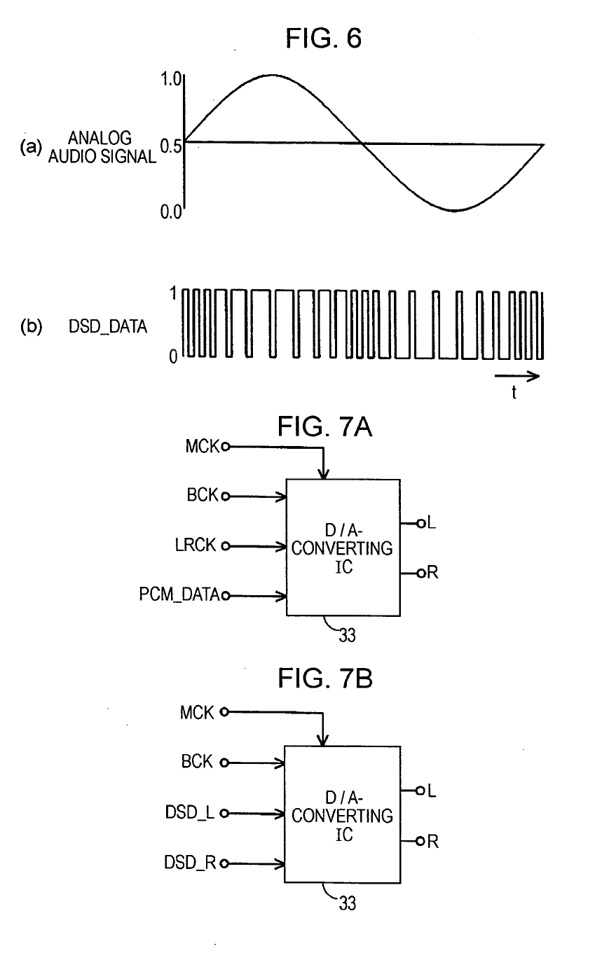

A case of PCM data PCM_DATA will be described. In this case, the interface circuit 31 outputs the PCM data PCM_DATA, the channel clock LRCK, the bit clock BCK, and the master clock MCK shown in FIG. 5. The PCM data PCM_DATA, the channel clock LRCK, the bit clock BCK, and the master clock MCK bypass processing of the conversion circuit 32, and are directly supplied to the IC (D/A converter circuit) 33.

In the IC (D/A converter circuit) 33, the bits L0 to L31 in the left channel of the PCM data PCM_DATA are separated from the bits R0 to R31 in the right channel of the PCM data PCM_DATA in accordance with the channel clock LRCK and the bit clock BCK. The bits L0 to L31 and the bits R0 to R31 are synchronized with each other, and the data, which are in synchronization with each other, are D/A-converted into analog audio signals L and R. The audio signals L and R are amplified by the amplifiers 34L and 34R, respectively. The amplified audio signals L and R are supplied to the speakers 35L and 35R, respectively, and are reproduced as music.

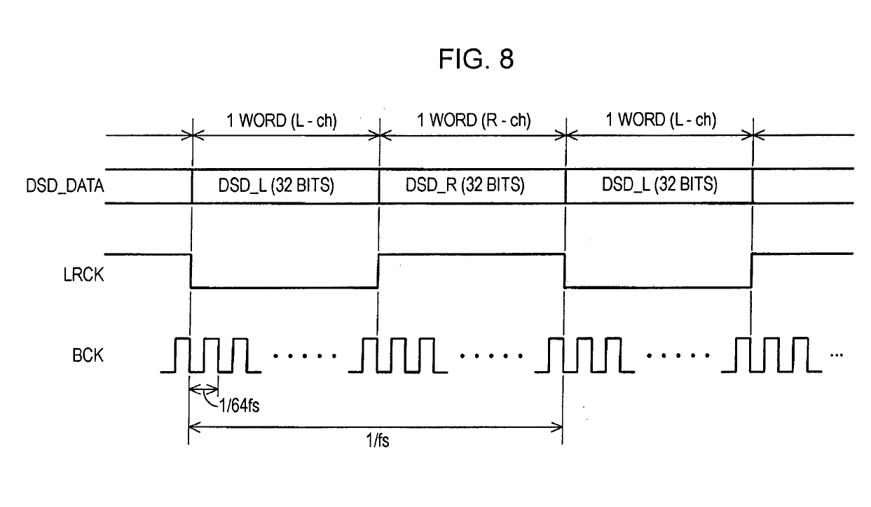

A case of DSD data DSD_DATA will now be described. In this case, the interface circuit 31 outputs the DSD data DSD_DATA, the channel clock LRCK, the bit clock BCK, and the master clock MCK shown in FIG. 8 to the conversion circuit 32. In the conversion circuit 32, the DSD data DSD_DATA is separated into a left-channel DSD dynamic range DSD_L and right-channel DSD data DSD_R. The left-channel DSD dynamic range DSD_L and the right-channel DSD data DSD_R are synchronized with each other, and the DSD data DSD_L and DSD_R, which are in synchronization with each other, are supplied to the IC (D/A converter circuit) 33. Thus, in the IC (D/A converter circuit) 33, the DSD data DSD_L and DSD_R are D/A-converted into analog audio signals L and R. The audio signals L and R are amplified by the amplifiers 34L and 34R, respectively. The amplified audio signals L and R are supplied to the speakers 35L and 35R, respectively, and are reproduced as music.

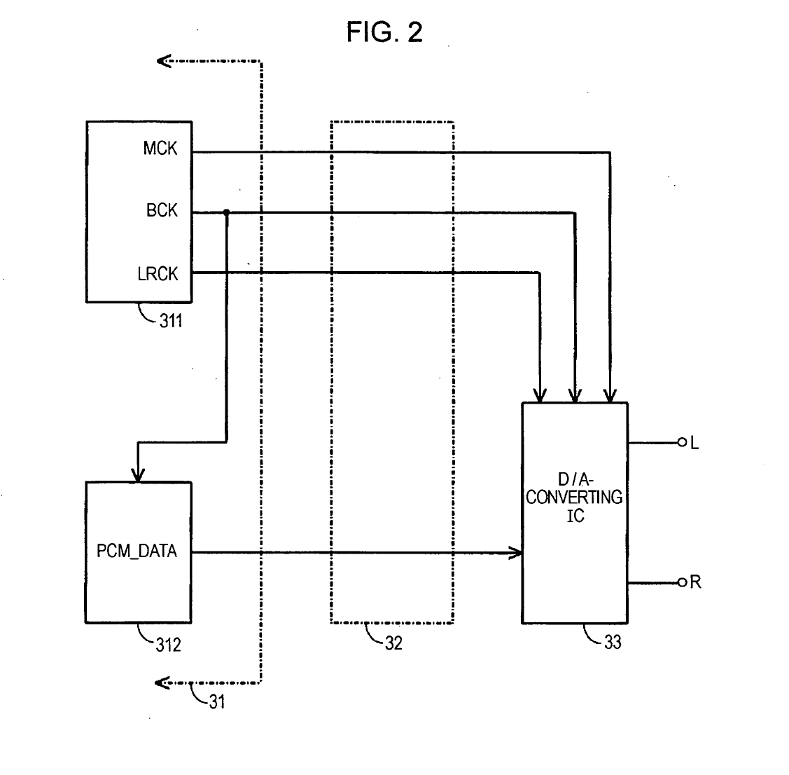

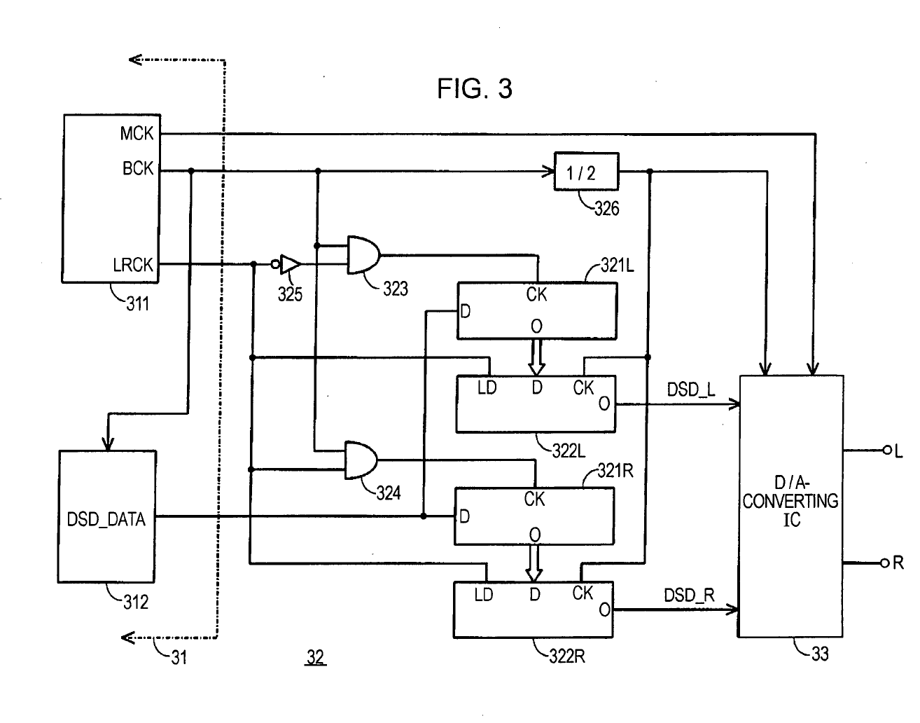

A configuration and an operation of the conversion circuit 32 will now be described. Referring to FIGS. 2 and 3, the interface circuit 31 is subjected to LSI integration together with other circuits, such as the communication interface 25. This LSI integrated circuit is referred to as an LSI 31 in FIGS. 2 and 3. The LSI (that is, the interface circuit) 31 includes a clock generator 311 and an output buffer 312.

Under the switching control of the CPU 21, the conversion circuit 32 is shifted to the state shown in FIG. 2 when music is reproduced from PCM data PCM_DATA, and the conversion circuit 32 is shifted to the state shown in FIG. 3 when music is reproduced from DSD data DSD_DATA.

When music is reproduced from PCM data PCM_DATA or DSD data DSD_DATA, the conversion circuit 32 performs corresponding processing described below.

A case where music is reproduced from PCM data PCM_DATA will be described. In this case, the conversion circuit 32 is shifted into the state shown in FIG. 2 under the control of the CPU 21. The PCM data PCM_DATA is extracted from the output buffer 312. The PCM data PCM_DATA passes through the conversion circuit 32, and is directly supplied to the IC (D/A converter circuit) 33. A channel clock LRCK, a bit clock BCK, and a master clock MCK are extracted from the clock generator 311. The channel clock LRCK, the bit clock BCK, and the master clock MCK pass through the conversion circuit 32, and are directly supplied to the IC (D/A converter circuit) 33. That is, in this case, the conversion circuit 32 is bypassed.

Thus, as described for the case where a file includes PCM data PCM_DATA, in the IC (D/A converter circuit) 33, the PCM data PCM_DATA is D/A-converted into left-channel and right-channel audio signals L and R, and the acquired signals L and R are output from the IC (D/A converter circuit) 33.

A case where music is reproduced from DSD data DSD_DATA will now be described. In this case, the conversion circuit 32 is shifted into the state shown in FIG. 3 under the control of the CPU 21. That is, the conversion circuit 32 includes 32-bit serial-in parallel-out shift registers 321L and 321R and 32-bit parallel-in serial-out shift registers 322L and 322R. Output terminals of the shift registers 321L and 321R are connected in parallel to input terminals of the shift registers 322L and 322R.

The DSD data DSD_DATA is extracted from the output buffer 312. The DSD data DSD_DATA is supplied as a data input to each of the shift registers 321L and 321R. In addition, a channel clock LRCK and a bit clock BCK are extracted from the clock generator 311. The bit clock BCK is supplied to an AND circuit 323, and the channel clock LRCK is supplied to the AND circuit 323 via an inverter 325. An AND output of the AND circuit 323 is supplied as a clock to the shift register 321L.

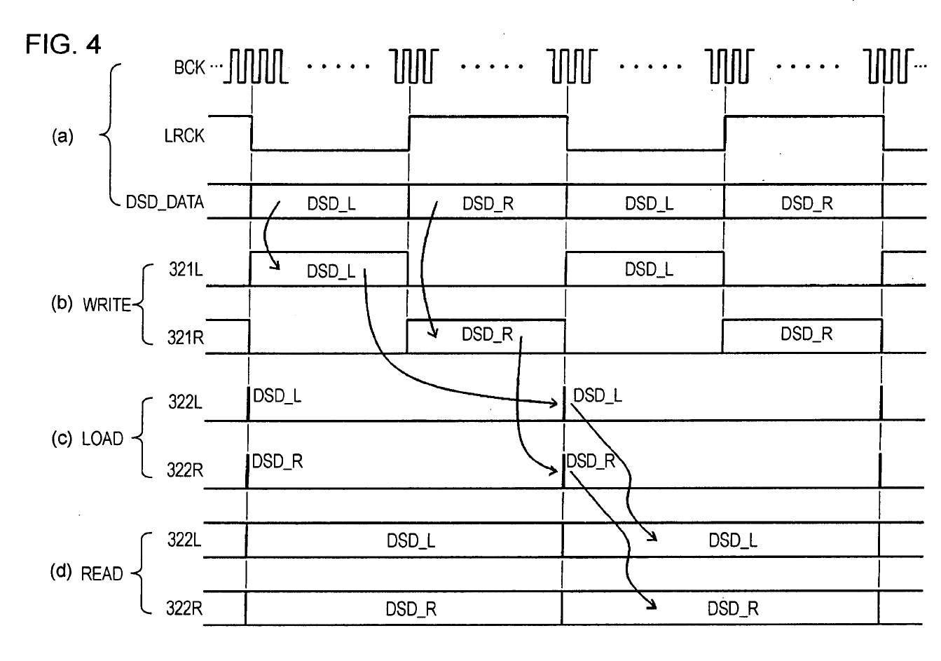

Thus, as shown in parts (a) and (b) of FIG. 4, (part (a) of FIG. 4 is equal to FIG. 8), during a period in which the channel clock LRCK is “0”, the DSD data DSD_DATA in this period, that is, left-channel DSD data DSD-L is sequentially written one by one to the shift register 321L.

In addition, the bit clock BCK output from the clock generator 311 is supplied to an AND circuit 324, and the channel clock LRCK is supplied to the AND circuit 324. An AND output of the AND circuit 324 is supplied as a clock to the shift register 321R. Thus, as shown in parts (a) and (b) of FIG. 4, during a period in which the channel clock LRCK is “1”, the DSD data DSD_DATA in this period, that is, right-channel DSD data DSD_R is sequentially written one by one to the shift register 321R.

That is, as shown in part (b) of FIG. 4, the left-channel DSD data DSD_L and the right-channel DSD data DSD_R are separately written to the shift registers 321L and 321R.

In addition, the channel clock LRCK output from the clock generator 311 is supplied as a load pulse to each of the shift registers 322L and 322R. As shown in part (c) of FIG. 4, every time the channel clock LRCK falls, the contents of the shift registers 321L and 321R are loaded to the shift registers 322L and 322R.

The bit clock BCK output from the clock generator 311 is supplied to a frequency divider 326 to be scaled down to a ½ frequency (a frequency of 32 fs), and the frequency-divided pulse is supplied as a clock input to each of the shift registers 322L and 322R. Thus, as shown in part (d) of FIG. 4, the left-channel DSD data DSD_L and the right-channel DSD data DSD_R are simultaneously output from the shift registers 322L and 322R continuously. The output DSD data DSD_L and DSD data DSD_R are supplied to the D/A-converting IC (D/A converter circuit) 33.

Thus, as described for the case where a file includes DSD data DSD_DATA, in the IC (D/A converter circuit) 33, the DSD data DSD_L and DSD_R are DIA-converted into a left-channel audio signal L and a right-channel audio signal R, and the acquired signals L and R are output from the IC (D/A converter circuit) 33.

As described above, with the conversion circuit 32, even if DSD data DSD_DATA output from the LSI (the interface circuit) 31 has the format shown in FIG. 8, that is, the LSI (the interface circuit) 31 does not support the format of the DSD data, the D/A-converting IC (D/A converter circuit) 33 is capable of D/A-converting the DSD data into analog signals L and R. Here, an expensive LSI is not used.

A case where PCM data PCM_DATA or DSD data DSD_DATA transmitted from the server 10 is reproduced as music in real time has been described above. However, an embodiment of the present invention is also applicable to a case where a storage device, such as a hard disk device or a non-volatile memory, is provided in the client 20 so that the transmitted PCM data PCM_DATA or DSD data DSD_DATA is stored in the storage device and is reproduced when necessary.

Alternatively, an embodiment of the present invention is also applicable to a case where PCM data PCM_DATA or DSD data DSD_DATA extracted from other recording media is directly reproduced or is stored in the storage device and then reproduced. In addition, the conversion circuit 32 may be realized by the processing of the CPU 21 or a digital signal processor (DSP). Furthermore, the conversion circuit 32 may be contained in the LSI (the interface circuit) 31.

It should be understood by those skilled in the art that various modifications, combinations, sub-combinations and alterations may occur depending on design requirements and other factors insofar as they are within the scope of the appended claims or the equivalents thereof.

What is claimed is:

1. A reproducing circuit comprising:
an output circuit that selectively outputs serial two-channel pulse code modulation data and serial two-channel direct stream digital data;
a digital-to-analog converter circuit that converts digital data into a first-channel analog signal and a second-channel analog signal; and
a conversion circuit,
wherein the two-channel pulse code modulation data includes first-channel pulse code modulation data and second-channel pulse code modulation data that are arranged alternately word by word,
wherein the two-channel direct stream digital data includes first-channel direct stream digital data and second-channel direct stream digital data that are arranged alternately word by word,
wherein when the two-channel pulse code modulation data is supplied to the digital-to-analog converter circuit, the digital-to-analog converter circuit converts the two-channel pulse code modulation data into the first-channel analog signal and the second-channel analog signal,
wherein when the first-channel direct stream digital data and the second-channel direct stream digital data are supplied to the digital-to-analog converter circuit, the digital-to-analog converter circuit converts the first-channel direct stream digital data and the second-channel direct stream digital data into the first-channel analog signal and the second-channel analog signal,
wherein the conversion circuit separates the two-channel direct stream digital data into the first-channel direct stream digital data and the second-channel direct stream digital data and includes shift registers that simultaneously output the first-channel direct stream digital data and the second-channel direct stream digital data, which are separated from each other,
wherein in order to convert the two-channel pulse code modulation data into the first-channel analog signal and the second-channel analog signal, the two-channel pulse code modulation data output from the output circuit is directly supplied to the digital-to-analog converter circuit, and
wherein in order to convert the two-channel direct stream digital data into the first-channel analog signal and the second-channel analog signal, the two-channel direct stream digital data output from the output circuit is subjected to the separation and synchronization by the conversion circuit and then supplied to the digital-to-analog converter circuit.

2. The reproducing circuit according to claim 1,
wherein the two-channel pulse code modulation data is digital data obtained by digitizing an analog signal based on a two's complement system, and
wherein the two-channel direct stream digital data is digital data obtained by digitizing the analog signal by ΔΣ modulation.
